(19) United States
(12) Patent Application Publication
(10) Pub. No.: US 2006/0026476 A1
(43) Pub. Date: Feb. 2, 2006

(54) Integrated circuit device and testing device

(75) Inventor: Yoshinori Nishida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 11/191,003

(22) Filed: Jul. 28, 2005

(30) Foreign Application Priority Data
Jul. 29, 2004 (JP) 2004-221539

(51) Int. Cl. G01R 31/28

(52) U.S. Cl. 714/730

(57) ABSTRACT

An integrated circuit device performs a delay test using scan path technique, including a pulse generator circuit generating a delay test clock pulse of a number according to an input pulse number control signal; and a scan path test circuit tested with the delay test clock pulse.

### BACKGROUND OF THE INVENTION

1. Field of the Invention

The present invention relates to integrated circuit devices and testing devices. Particularly, the invention relates to an integrated circuit device and a testing device that perform delay test using scan path technique.

2. Description of Related Art

An integrated circuit device (referred to hereinafter as the LSI), goes through manufacturing test (hereinafter as the test) to discriminate between superior and inferior products after it is manufactured by a series of manufacturing processes. With the development of large-scale and high-density LSIs, Design For Test (DFT) that designs a circuit so as to facilitate a test is used to increase the efficiency of LSI test.

A well-known test with DFT is a delay test using scan path technique. The scan path technique facilitates a test. It produces a chain of a plurality of flip-flops (hereinafter as F/Fs) of an LSI, which is called a scan chain, to form a shift register, and then inputs a test pattern through an external terminal and reads out an operating result of a tested circuit such as a combinational circuit or Random-Logic through the scan chain. The F/Fs connected in the scan chain are called scan F/Fs.

For example, the delay test using the scan path supplies a tested circuit with a normal operation clock pulse defined by product specification from an LSI tester and checks if failure occurs due to delay.

The operating frequencies of the LSI now reach as high as GHz, which is too high-speed to perform the delay test with a signal directly supplied from the outside of the LSI. Performing the delay test on such an LSI with use of an LSI tester requires a very expensive high-performance and high-speed tester for stable generation of high-frequency clocks. This increases testing costs, causing LSI manufacturing costs to rise.

To overcome this drawback, a method of generating a high-frequency pulse inside an LSI to be tested and a test board on which an LSI is mounted when testing is known as described in Japanese Unexamined Patent Publication No. 2003-43109 (Hideharu Ozaki), for example.

FIG. 7 is a conventional LSI testing device taught by Ozaki. The LSI testing device has a test board 701, an LSI 702 and a clock oscillator 703 that are mounted on the test board 701 as shown in FIG. 7. The LSI 702 includes a tested circuit. The clock oscillator 703 generates a test clock with a predetermined cycle. The LSI 702 has a phase-locked loop (PLL) 704, a pulse generator circuit 705, and a scan path test circuit 707. The PLL 704 multiplies the test clock frequency to a predetermined frequency. The pulse generator circuit 705 generates two pulses for the delay test. The scan path test circuit 707 includes a tested circuit and the scan chain.

The pulse generator circuit 705 fixedly generates two pulses, giving a timing to generate two pulses to a control pulse (see FIGS. 2 and 3 of Japanese Unexamined Patent Publication No. 2003-43109).

FIG. 8A shows the scan path test circuit of the conventional LSI testing device, and FIG. 8B shows a timing chart of the signal used in the test. As shown in FIG. 8A, the scan path test circuit 707 has a tested circuit 801 and scan F/Fs 802 connected to an input stage (previous stage) and an output stage (subsequent stage) of the tested circuit 801. A plurality of scan F/Fs 802 are connected to form a scan chain 803. The scan F/Fs 802 are switched between scan mode to perform scan shift operation and normal operation mode to perform normal operation by a scan enable signal SE.

As shown in FIG. 8B, the delay test involves Shift operation to transfer data through the scan chain 803, Launch operation to start testing on the tested circuit 801, and Capture operation to acquire the operating result of the tested circuit 801.

In the delay test process, Shift operation first sets an initial value to each scan F/F 802. In Shift operation, the scan enable signal SE is set to “1” or “High” to switch the scan F/Fs 802 constituting the scan chain 803 to the scan mode, and a predetermined clock (CLK) is input to transfer the initial value from a scan-in terminal SIN. This clock has enough margin compared to a clock defined by product specification as shown in FIG. 8B.

Then, Launch and Capture operation carries out testing on the tested circuit 801. In Launch and Capture operation, the scan enable signal SE is set to “0” or “Low” to switch the scan F/Fs 802 to the normal operation mode, and a predetermined clock is input to perform testing. This clock is a two-pulse clock with two clock pulses having a clock interval (At-Speed in FIG. 8B) corresponding to the frequency of the clock defined by product specification, which is 500 MHz, for example, as shown in FIG. 8B. The operation supplies the initial value from the scan F/F 802 of the input stage to the tested circuit 801 in the first clock pulse, and then latches the operating result of the tested circuit 801 into the scan F/F 802 of the output stage in the second clock pulse.

After that, Shift operation is performed again to acquire the operating result. In Shift operation, the scan enable signal SE is set to “1” to switch the scan F/Fs 802 to the scan mode, a predetermined clock is input to supply the operating result to a scan-out terminal SOUT. The operation then compares the operating result acquired from the scan-out terminal SOUT with an expected value, thereby checking if failure has occurred due to delay of the tested circuit 801.

The scan F/F used for the delay test is an edge trigger type that detects the edge of a clock pulse and performs latching and shifting. For example, the scan F/F latches an input signal when detecting the edge of a clock pulse and outputs it as an output signal. The F/F is identified by which edge it detects. The F/F that detects a rising edge of a clock pulse is called a positive edge F/F (hereinafter as POS-F/F). The F/F that detects a falling edge of a clock pulse is called a negative edge F/F (hereinafter as NEG-F/F). Clock pulse formats include Return to Zero (RZ) that bases on “0” and Return to One (RO) that bases on “1” according to signal polarity.

In the delay test, a clock pattern used for the test varies by the combination of the scan F/F placed in the input stage of the tested circuit and the scan F/F placed in the output stage of the tested circuit. FIG. 9 shows the relationship between the type of the scan F/F in the input and output stages of the tested circuit and the clock pattern used for the test. In FIG. 9, the cases (a) to (d) in the upper column are when the clock is RZ, and the cases (e) to (h) in the lower column are when the clock is RO.

If the F/Fs in the input stage and the output stage are both POS-F/F, the test is conducted with the clock pattern of two clock pulses, and it performs Launch operation at the rising edge of the first clock and Capture operation at the rising edge of the second clock as shown in the cases (a) and (e) of FIG. 9.

If the F/Fs in the input stage and the output stage are both NEG-F/F, the test is conducted with the clock pattern of two clock pulses, and it performs Launch operation at the falling edge of the first clock and Capture operation at the falling edge of the second clock as shown in the cases (b) and (f) of FIG. 9.

If the scan F/F in the input stage is POS-F/F and that in the output stage is NEG-F/F, the clock pattern differs between RZ and RO formats. When the clock is RZ, the test is conducted with the clock pattern of one clock pulse, and it performs Launch operation at the rising edge of the clock and Capture operation at the falling edge of the same clock as shown in the case (c) of FIG. 9. On the other hand, when the clock is RO, the test is conducted with the clock pattern of two clock pulses, and it performs Launch operation at the rising edge of the first clock and Capture operation at the falling edge of the second clock as shown in the case (g) of FIG. 9.

If the scan F/F in the input stage is NEG-F/F and that in the output stage is POS-F/F, the clock pattern differs between RZ and RO formats. When the clock is RZ, the test is conducted with the clock pattern of two clock pulses, and it performs Launch operation at the falling edge of the first clock and Capture operation at the rising edge of the second clock as shown in the case (d) of FIG. 9. On the other hand, when the clock is RO, the test is conducted with the clock pattern of one clock pulse, and it performs Launch operation at the falling edge of the clock and Capture operation at the rising edge of the same clock as shown in the case (h) of FIG. 9.

The present invention, however, has recognized that the conventional LSI testing device described above has the following problem. Since the LSI testing device merely gives a timing to generate two pulses to a control pulse and fixedly generates two pulses, a pulse generator circuit in the LSI can only generate two-pulse clocks. It is thereby incapable of conducting the test using one-pulse clock as the cases (c) and (h) of FIG. 9. The testing device therefore cannot detect any defects in this part to reduce a failure detection rate, causing faults to occur frequently in the market.

### SUMMARY OF THE INVENTION

According to one aspect of the invention, there is provided an integrated circuit device performing a delay test using scan path technique, including a pulse generator circuit generating a delay test clock pulse of a number according to an input pulse number control signal; and a scan path test circuit tested with the delay test clock pulse. Since the integrated circuit device generates the number of pulses according to a pulse number control signal, it can conduct a delay test using a clock having a given number of pulses. It is thereby possible to conduct a test regardless of the type of a scan F/F or a clock signal.

According to another aspect of the invention, there is provided a testing device of an integrated circuit device, including a test board for mounting an integrated circuit device to be tested; and a clock oscillator mounted on the test board and generating a clock pulse to be input to a pulse generator circuit, wherein the integrated circuit device includes a pulse generator circuit generating a delay test clock pulse of a number according to an input pulse number control signal, and a scan path test circuit tested with the delay test clock pulse. Since the testing device of the integrated circuit device generates the number of pulses according to a pulse number control signal, it can conduct a delay test using a clock having a given number of pulses. It is thereby possible to conduct a test regardless of the type of a scan F/F or a clock signal.

According to yet another aspect of the invention, there is provided an integrated circuit device including a scan path test circuit connecting flip-flops for scan shifting and performing a test by switching between scan shift mode and normal operation mode, wherein the flip-flops in the normal operation mode are operated with a pulse of a number according to an input pulse number control signal. The integrated circuit device conducts a test using flip-flops in scan shit mode and allows the flip-flops to operate in normal mode also by using the number of pulses according to a pulse number control signal. An internal circuit can thereby operate efficiently both in the scan shift mode and the normal mode.

The above integrated circuit device may has a pulse generator circuit generating a pulse of a number according to the input pulse number control signal. It is thereby possible to efficiently generate a clock having a given number of pulses.

The present invention provides an integrated circuit device and a testing device capable of conducting a delay test using a clock having a given number of pulses.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing the configuration of a testing device of an integrated circuit device of the invention;

FIG. 2 is a circuit diagram showing the configuration of a scan path test circuit of the invention;

FIG. 3 is a circuit diagram showing the configuration of a pulse generator circuit of the invention;

FIG. 4 is a timing chart showing the operation of a pulse generator circuit of the invention;

FIG. 5 is a view to describe a testing method of an integrated circuit device of the invention;

FIG. 6 is a view to describe a testing method of an integrated circuit device of the invention;

FIG. 7 is a block diagram showing the configuration of a conventional integrated circuit device;

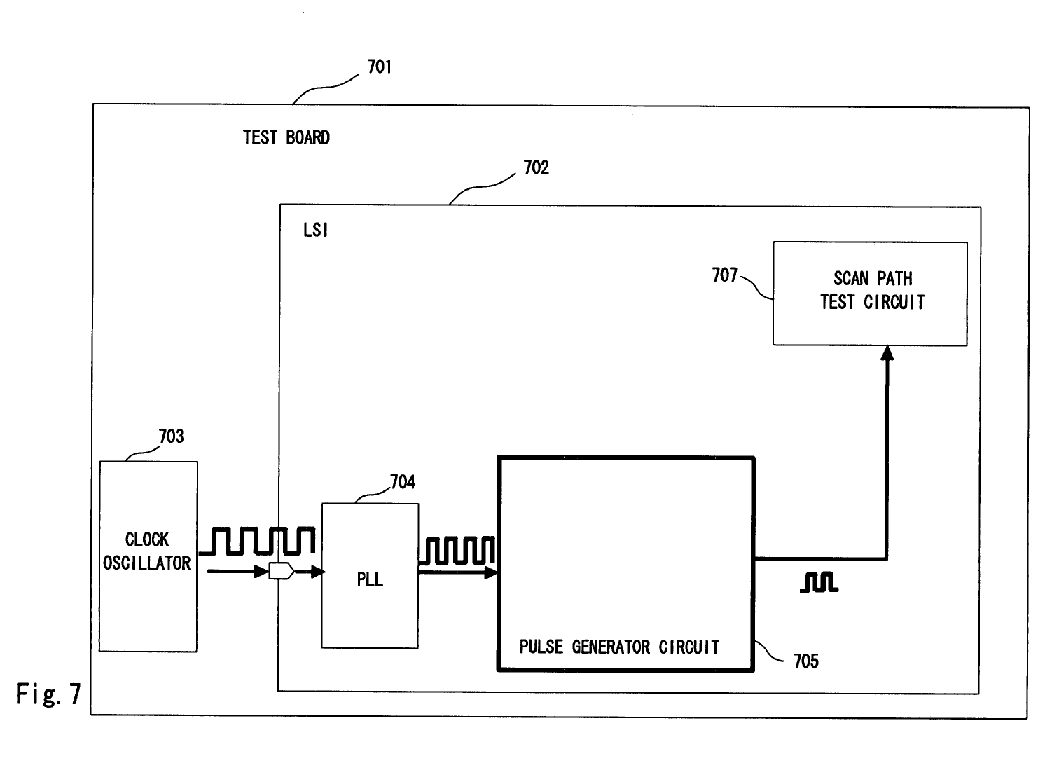

FIGS. 8A and 8B are views to describe a testing method of a conventional integrated circuit device; and

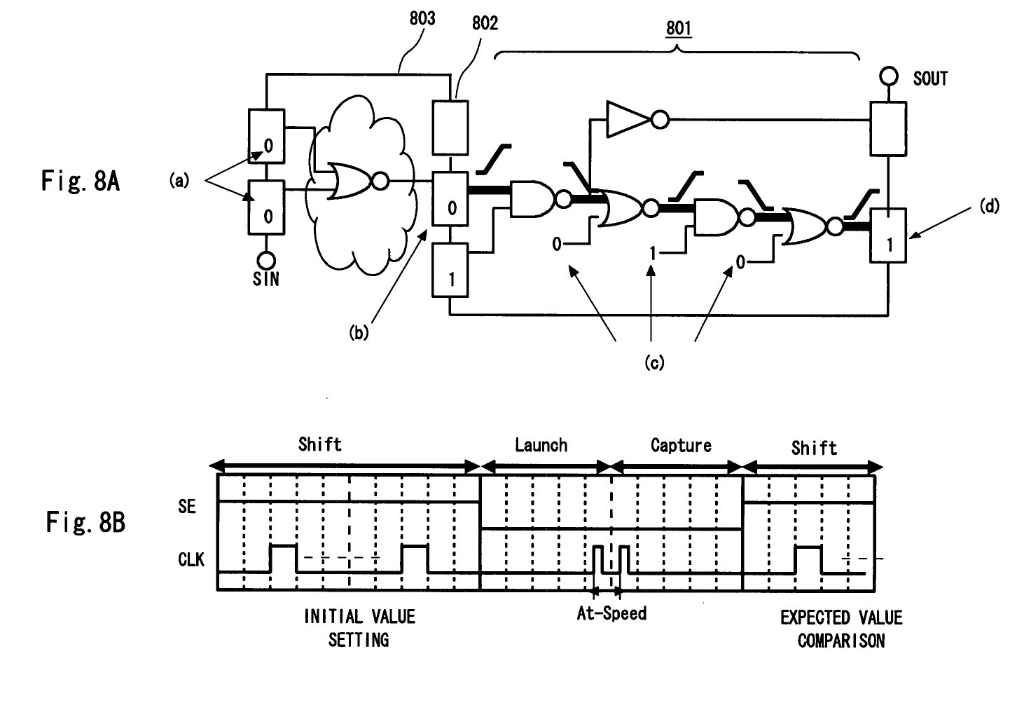

FIG. 9 is a view to describe the relationship between a scan flip-flop and a clock signal of an integrated circuit device.

### DESCRIPTION OF THE PREFERRED EMBODIMENTS

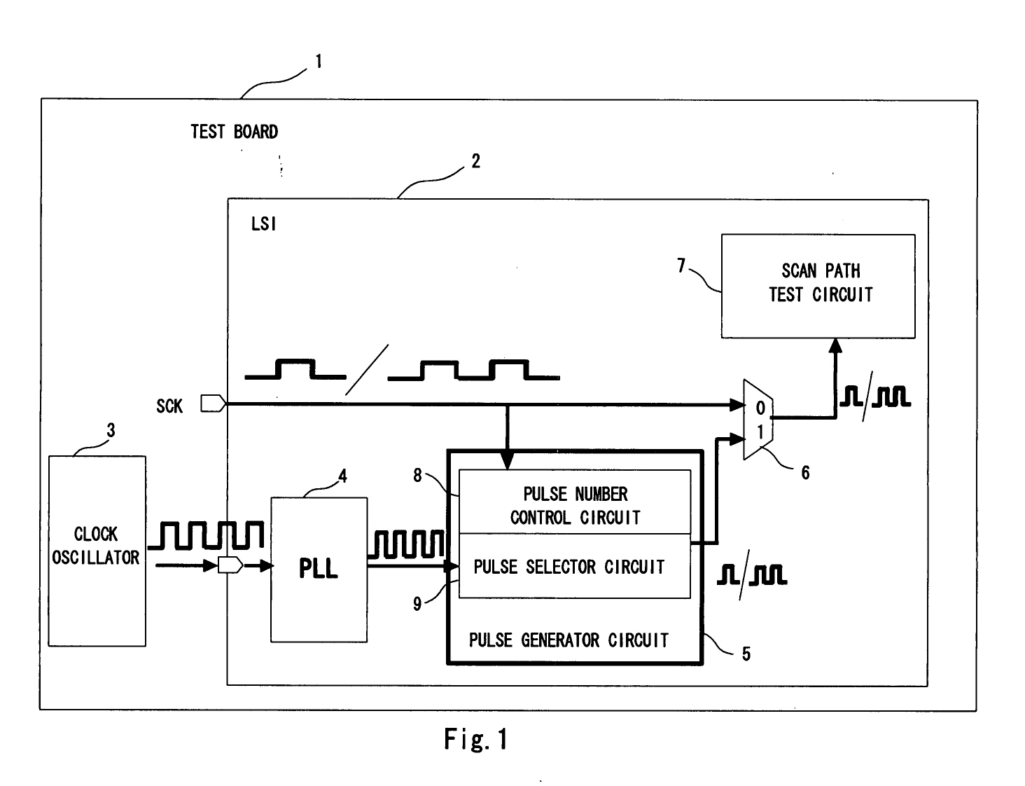

The configuration of an LSI testing device according to an embodiment of the invention is described hereinafter with reference to the block diagram of FIG. 1. The LSI testing device performs a delay test using scan path technique. Even when a tester can only generate a low frequency clock, the device can generate a high frequency clock inside the LSI and conduct a desired delay test.

As shown in FIG. 1, the LSI testing device has a test board 1, an LSI 2 detachably mounted on the test board 1, and a clock oscillator 3 mounted on the test board 1. The LSI 2 has a PLL 4, a pulse generator circuit 5, a multiplexer 6, and a scan path test circuit 7.

The LSI 2 also has terminals for inputting a scan clock SCK and a test clock of the clock oscillator 3. Further, though not shown in FIG. 1, it has other terminals such as a scan-in terminal SIN for inputting a test pattern, a scan-out terminal SOUT for outputting a test operating result, and a scan mode control terminal SMC for inputting a scan enable signal SE to switch test mode.

For example, the LSI 2 to go through a delay test is mounted on the test board 1. A tester supplies a scan clock SCK and a test pattern to the LSI 2 and then acquires operating results, thereby conducting the delay test. The input test pattern is previously generated by Automatic Test Pattern Generator (ATPG) tool or the like.

The clock oscillator 3 generates a test clock of a given cycle and outputs it to the LSI 2. The clock oscillator 3 does not have to generate a high frequency clock, and the frequency may be 50 to 100 MHz, for example. Further, though the clock oscillator 3 is placed outside the LSI 2 in this example, it may be placed inside the LSI 2 and, if so, it may also serve as a clock oscillator for normal operation. Though the test clock is generated by the clock oscillator 3 mounted on the test board 1, it may be generated by another device such as an LSI tester.

The PLL 4 multiplies the test clock generated by the clock oscillator 3 to a predetermined frequency. It also regulates the waveform of the test clock and outputs a PLL clock (PLL_CLK). For example, the PLL 4 multiplies the test clock frequency of 50 MHz by 10 and outputs a PLL clock of 500 MHz. The PLL 4 may be eliminated if there is no need to multiply the test clock frequency nor regulate the waveform. In this case, the test clock generated by the clock oscillator 3 is input to the pulse generator circuit 5 as it is. Further, though the PLL 4 is placed inside the LSI 2 in this example, it may be placed outside the LSI 2 and, if so, it may also serve as a PLL for normal operation.

The pulse generator circuit 5 generates a delay test clock SCK0. In this embodiment, the pulse generator circuit 5 can selects a given number of pulses and generates a desired clock. Using a scan clock SCK as a pulse number control signal, the pulse generator circuit 5 extracts a desired number of pulses from a PLL clock of the PLL 4 or a test clock according to the number of pulses of the scan clock SCK. Though the number of pulses to be extracted is identified by the scan clock SCK in this example, it may be identified by another way. For example, it is also possible to input a plurality of bits in parallel, not in serial like the scan clock SCK. Further, the pulse generator circuit 5 has a pulse number control circuit 8 and a pulse selector circuit 9 as described later.

The multiplexer 6 is a selector circuit that selects one from the scan clock SCK and the delay test clock SCK0 generated by the pulse generator circuit 5 and supplies the selected one to the scan path test circuit 7. The multiplexer 6 switches the signal to select according to a control signal supplied from the outside. For example, the selection may depend on a scan enable signal SE, which selects the scan clock SCK in Shift operation in the delay test while selecting the delay test clock SCK0 in Launch and Capture operation.

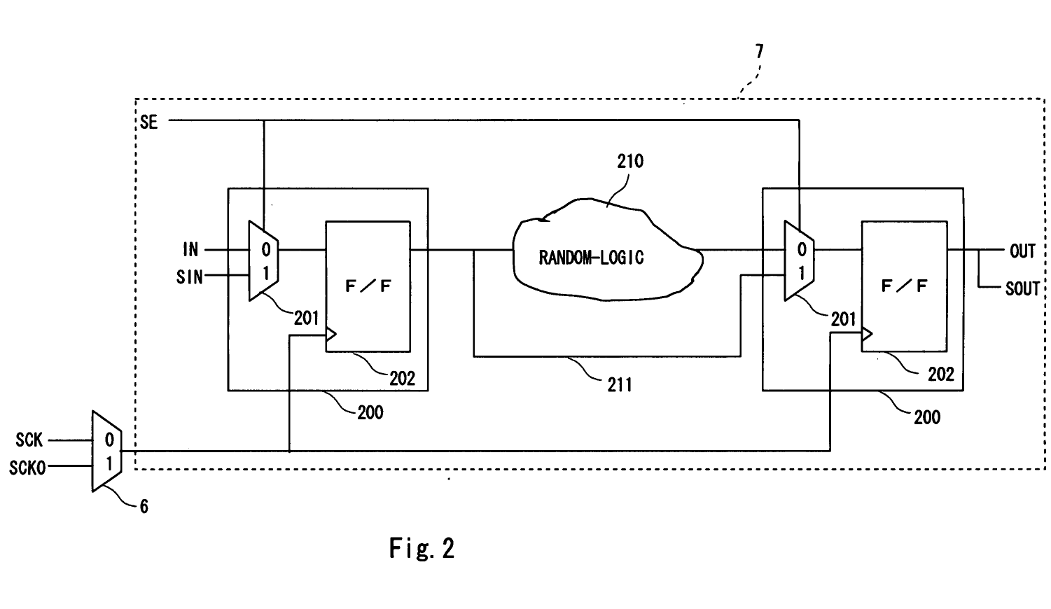

The scan path test circuit 7 is a circuit on which the delay test is carried out using scan path technique. It includes a tested circuit and a scan chain. The configuration of the scan path test circuit 7 is described hereinafter with reference to the circuit diagram of FIG. 2.

As shown in FIG. 2, the scan path test circuit 7 has a tested circuit 210 and scan F/Fs connected to an input stage (previous stage) and an output stage (subsequent stage) of the tested circuit 210. A plurality of scan F/F 200 are connected to form a scan chain 211.

The scan F/F 200 performs scan shifting on a test pattern or the like during the scan mode while operating as a normal internal circuit during the normal operation mode. The scan F/F 200 has a multiplexer 201 and a F/F 202. The multiplexer 201 receives a normal operation signal from a normal input terminal IN or the like during the normal operation mode and receives a scan shift signal from a scan-in terminal SIN or the like during the scan mode. The multiplexer 201 selects one from the normal operation signal and the scan shift signal according to the scan enable signal SE and outputs the selected one to the F/F 202.

The F/F 202 latches the signal supplied from the multiplexer 201 in accordance with an input clock and transfers the latched signal to the circuit in the subsequent stage. The clock supplied to the F/F 202 is output from the multiplexer 6, which is either the scan clock SCK or the delay test clock SCK0.

During Shift operation in the delay test, the test pattern from the scan-in terminal SIN and the operating result of the tested circuit 210 are input to the scan F/F 200 and scan-shifted according to the scan clock SCK.

During Launch operation, the input signal to the scan F/F 200 is supplied to the tested circuit 210 according to the delay test clock SCK0. During Capture operation, the operating result of the tested circuit 210 is latched into the scan F/F 200 in accordance with the delay test clock SCK0.

The scan F/F 200 of FIG. 2 is a multiplexer scan F/F which uses both the scan shift clock and the normal operation clock. It is, however, not limited thereto and the delay test may be performed similarly with another type of scan F/F. For example, it may be a scan F/F of a Level Sensitive Scan Design (LSSD) type to which the scan shift clock and the normal operation clock are applied individually.

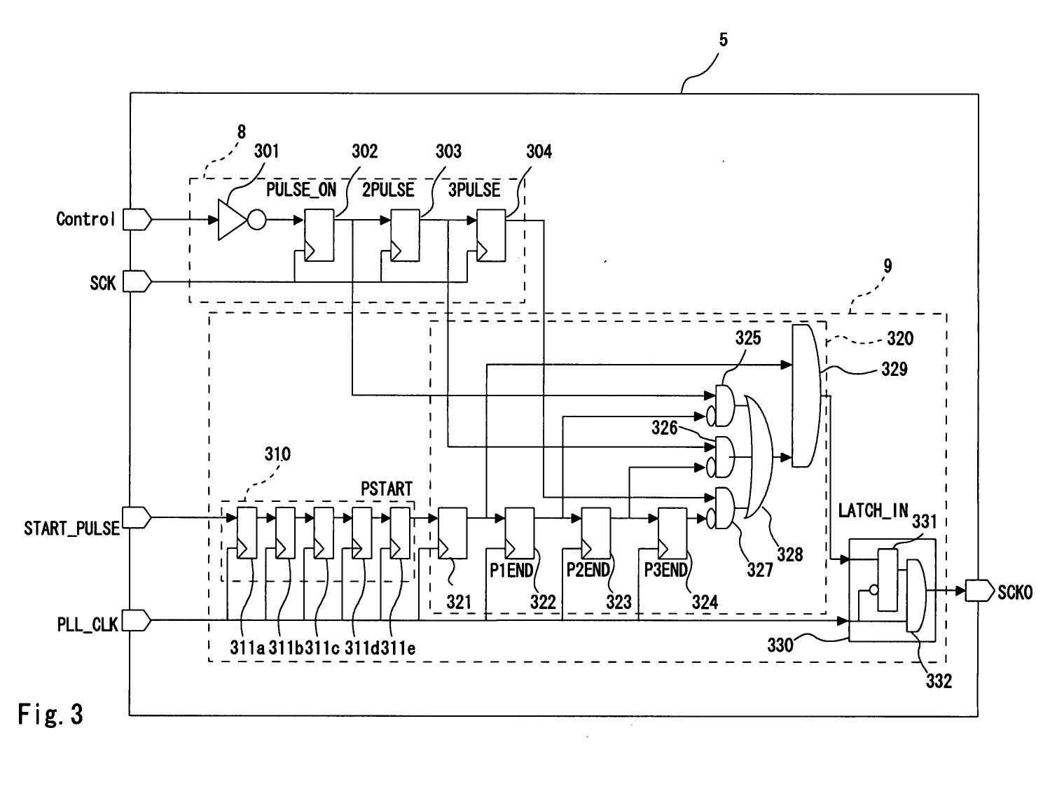

The configuration of a pulse generator circuit of this embodiment is described hereinafter with reference to the circuit diagram of FIG. 3. The pulse generator circuit 5 has the pulse number control circuit 8 and the pulse selector circuit 9.

The pulse number control circuit 8 stores the number of clock pulses to be output from the pulse generator circuit. The pulse number control circuit 8 receives Control signal, which is an external signal, and a scan clock SCK. The pulse number control circuit 8 is a counter circuit to count the number of pulses of the scan clock SCK. The counting operation is controlled by Control signal.

The pulse number control circuit 8 has an inverter 301 and F/Fs 302, 303 and 304. The F/Fs 302, 303 and 304 form a shift register and shift the value of Control signal according to the scan clock SCK, thereby counting the number of scan clock SCK and retaining the value.

The number of pulses, 1, 2, or 3, can be represented by the value latched into the F/Fs 302, 303 and 304. The F/F 302 indicates if the first pulse exists, and the output signal of the F/F 302 is shown as “PULSE_ON”. The F/F 303 indicates if the second pulse exists, and the output signal of the F/F 303 is shown as “2PULSE”. The F/F 304 indicates if the third pulse exists, and the output signal of the F/F 304 is shown as “3PULSE”.

For example, if the number of pulses is 1, PULSE_ON is “1”, 2PULSE is “0”, and 3PULSE is “0”. If the number of pulses is 2, PULSE_ON is “1”, 2PULSE is “1”, and 3PULSE is “0”. If the number of pulses is 3, PULSE_ON is “1”, 2 PULSE is “1”, and 3PULSE is “1”.

Control signal is input to the inverter 301, and the output signal of the inverter 301 is input to an input terminal (D terminal or the like) of the F/F 302. The signal output from the output terminal (Q terminal or the like) of the F/F 302 is then input to the input terminal of the F/F 303. The signal output from the output terminal of the F/F 303 is then input to the input terminal of the F/F 304. The scan clock SCK is input to the clock terminals of the F/Fs 302, 303 and 304. The output signals of the F/Fs 302, 303 and 304 are supplied to the pulse selector circuit 9. For example, if Control signal changes from “1” to “0”, the inverter 301 outputs “1”. Then, the output “1” is shifted in the order of the F/Fs 302, 303 and 304 according to the number of pulses of the scan clock SCK.

The pulse selector circuit 9 extracts the delay test clock SCK0 from the PLL clock (PLL_CLK) multiplied by the PLL 4. The pulse selector circuit 9 starts outputting the delay test clock SCK0 in accordance with START_PULSE, which is a control signal supplied from the outside, and selects and outputs the number of clocks latched in the pulse number control circuit 8. For example, after START_PULSE changes from “0” to “1”, it outputs the delay test clock SCK0 by the number of pulses set to the pulse number control circuit 8.

The pulse selector circuit 9 has a timing control circuit 310, an output period detector circuit 320, and a clock output circuit 330. The timing control circuit 310 controls the timing of START_PULSE and PLL_CLK. It may be eliminated if the timing of START_PULSE and PLL_CLK is secured.

The timing control circuit 310 is formed of a plurality of F/F 311 and it has five F/Fs 311a to 311e in this example. The F/Fs 311a to 311e form a shift register, which shifts the signal of START_PULSE in accordance with PLL_CLK. The timing control circuit 310 outputs START_PULSE which is delayed by the clocks corresponding to the number of the F/Fs 311 to the output period detector circuit 320. For example, if START_PULSE changes from “0” to “1”, the “1” is shifted in the order of the F/Fs 311a to 311e in accordance with PLL_CLK and then supplied to the output period detector circuit 320 after five clocks.

START_PULSE is input to the input terminal of the F/F 311a, and the signal output from the output terminal of the F/F 311a is then input to the F/F 311b in the subsequent stage. The output signals of the F/Fs 311b, 311c, and 311e are also input to the F/F 311 in the subsequent stage in the same manner, and eventually the output signal from the F/F 311e is supplied to the output period detector circuit 320. PLL_CLK is input to the clock terminals of the F/Fs 311a to 311e.

The output period detector circuit 320 determines a period to output the clock according to the number latched into the pulse number control circuit 8. The output period detector circuit 320 has F/Fs 321 to 324, AND circuits 325 to 327, an OR circuit 328, and an AND circuit 329.

The F/Fs 321 to 324 form a shift register and shift the signal of START_PULSE delayed by the timing control circuit 310 in accordance with PLL_CLK.

The F/F 321 controls the timing to start outputting the pulse, and the output signal of the F/F 321 is represented by “PSTART”. The F/F 322 controls the timing to end the first pulse, and the output signal of the F/F 322 is represented by “P1END”. Similarly, the F/F 323 controls the timing to end the second pulse, and the output signal of the F/F 323 is represented by “P2END”. The F/F 324 controls the timing to end the third pulse, and the output signal of the F/F 324 is represented by “P3END”.

The output signal of the timing control circuit 310 is input to the input terminal of the F/F 321, and the signal output from the output terminal of the F/F 321 is then input to the F/F 322 in the subsequent stage. The output signals of the F/Fs 322 and 323 are also input to the F/F in the subsequent stage in the same manner. PLL_CLK is input to the clock terminals of the F/Fs 321 to 324. The output signals of the F/Fs 321 to 324 are respectively supplied to the AND circuits 329, 325, 326 and 327.

The AND circuits 325, 326 and 327, the OR circuit 328, and the AND circuit 329 detect the period for clock output according to the outputs from the F/F 302 to 304 of the pulse number control circuit 8. The AND circuit 325 detects the end of the first pulse based on the output signal (PULSE_ON) of the F/F 302 and the output signal (P1END) of the F/F 322. The AND circuit 325 obtains and outputs a logical AND between the output signal of the F/F 302 and an inverted signal of the output signal of the F/F 322. Thus, the AND circuit 325 outputs “1” if PULSE_ON is “1” and P1END is “0” while it outputs “0” in the other cases.

The AND circuit 326 detects the end of the second pulse based on the output signal (2PULSE) of the F/F 303 and the output signal (P2END) of the F/F 323. The AND circuit 326 obtains and outputs a logical AND between the output signal of the F/F 303 and an inverted signal of the output signal of the F/F 323. Thus, the AND circuit 326 outputs “1” if 2PULSE is “1” and P2END is “0” while it outputs “0” in the other cases.

The AND circuit 327 detects the end of the third pulse based on the output signal (3PULSE) of the F/F 304 and the output signal (P3END) of the F/F 324. The AND circuit 327 obtains and outputs a logical AND between the output signal of the F/F 304 and an inverted signal of the output signal of the F/F 324. Thus, the AND circuit 327 outputs “1” if 3PULSE is “1” and P3END is “0” while it outputs “0” in the other cases.

The OR circuit 328 detects the end of the first to third pulses based on the outputs of the AND circuits 325 to 327. The OR circuit 328 obtains and outputs a logical OR of the AND circuits 325 to 327. Thus, the OR circuit 328 outputs “1” if any of the output signals from the AND circuits 325 to 327 is “1” while it outputs “0” in the other cases.

The AND circuit 329 detects the start of the pulse output and the end of the first to third pulses based on the output signal (PSTART) of the F/F 321 and the output signal of the OR circuit 328. The AND circuit 329 obtains and outputs a logical AND between the output signal of the F/F 321 and the output signal of the OR circuit 328. Thus, the AND circuit 329 outputs “1” if PSTART is “1” and the output signal of the OR circuit 328 is “1” while it outputs “0” in the other cases.

The clock output circuit 330 outputs PLL_CLK during the period detected by the output period detector circuit 320. The clock output circuit 330 has a F/F 331 and an AND circuit 332.

The F/F 331 is a latch circuit to latch the signal supplied from the output period detector circuit 320. The input signal is represented by “LATCH_IN”. The F/F 331 latches the output signal of the output period detector circuit 320 in accordance with PLL_CLK.

The output signal of the output period detector circuit 320 is input to the input terminal of the F/F 331, and the output signal of the F/F 331 is input to the AND circuit 332. An inverted signal of PLL_CLK is input to the clock terminal of the F/F 331.

The AND circuit 332 outputs delay test clock SCK0 based on the output signal of the F/F 331 and PLL_CLK. The AND circuit 332 obtains and outputs a logical AND between the output signal of the F/F 331 and PLL_CLK. Thus, the AND circuit 332 outputs “1” if the output signal of the F/F 331 is “1” and PLL_CLK is “1” while it outputs “0” in the other cases.

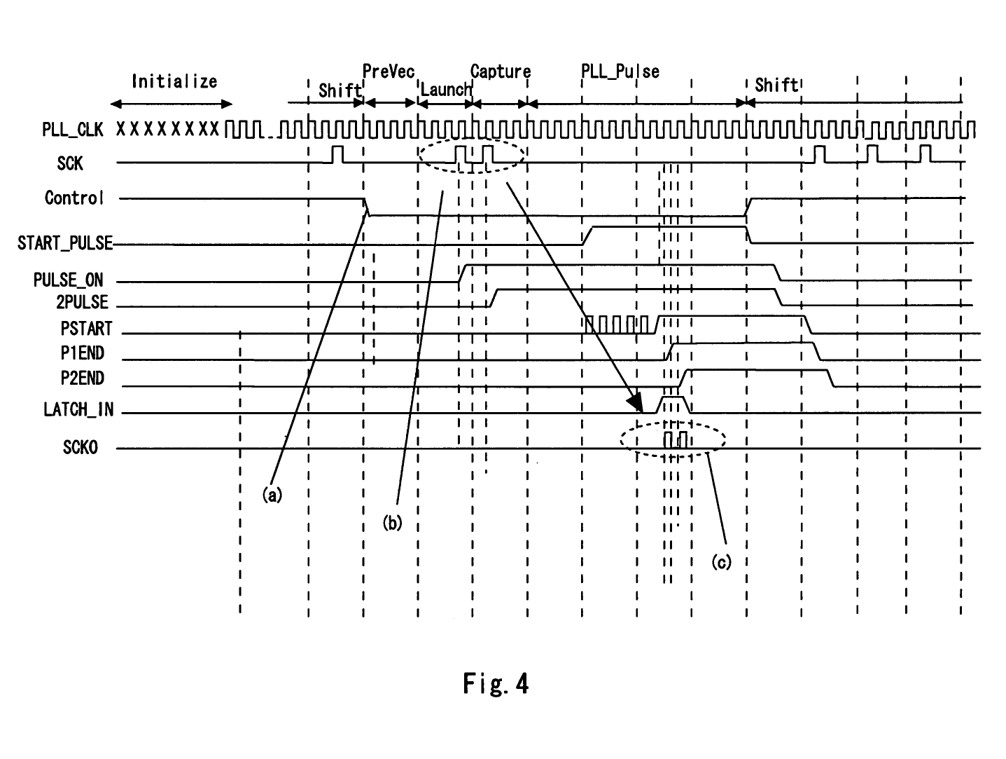

The operation of the pulse generator circuit of this embodiment is described hereinafter with reference to the timing chart of FIG. 4. FIG. 4 shows the case where the pulse generator circuit 5 generates two-pulse.

The operation to generate a desired delay test clock SCK0 is as follows. First, after initializing the PLL 4, the PLL 4 multiplies a test clock supplied from the clock oscillator 3 to generate a high-speed clock PLL_CLK.

Then, Control signal of the pulse generator circuit 5 is changed from “1” to “0” to enter the count mode as indicated by (a) in FIG. 4. The pulse of the scan clock SCK is input and the pulse number control circuit 8 performs shift operation. The number of the input pulse is thereby counted and set to the pulse number control circuit 8 as indicated by (b) in FIG. 4. Thus, PULSE_ON becomes “1” according to the first pulse of the scan clock SCK, and 2PULSE becomes “1” according to the second pulse of the scan clock SCK. The number of pulses thus set is the number of pulses of the delay test clock SCK0.

Then, START_PULSE is changed from “0” to “1” in order to output the delay test clock. After the timing control circuit 310 delays it by predetermined clocks, PSTART becomes “1”. P1END becomes “1” in the next clock timing, and then P2END also becomes “1” in the subsequent clock timing.

LATCH_IN is “1” from when PSTART becomes “1” to when P2END becomes “1”. While LATCH_IN is “1”, PLL_CLK is extracted and two pulses of delay test clock SCK0 are output as indicated by (c) of FIG. 4.

The operation is detailed hereinafter in further detail. When START_PULSE is “0”, PSTART is still “0”, and the AND circuit 329 outputs “0” as LATCH_IN. If START_PULSE becomes “1” and PSTART also becomes “1”, the AND circuit 329 outputs LATCH_IN in accordance with the outputs of the AND circuits 325 to 327.

At the timing when PSTART becomes “1”, P1END and P2END are “0” and PULSE_ON and 2PULSE are “1”. Thus, the AND circuits 325 and 326 output “1” and LATCH_IN thereby changes from “0” to “1”. The clock output circuit 330 outputs the first pulse at this time.

Then, at the timing when P1END becomes “1”, PLEND is “1” and P2END is “0”, and PULSE_ON and 2PULSE are “1”. Thus, the AND circuit 325 outputs “0” and the AND circuit 326 outputs “1”, and LATCH_IN thereby stays “1”. The clock output circuit 330 outputs the second pulse at this time.

Further, at the timing when P2END becomes “1”, P1END and P2END are “1”, and PULSE_ON and 2PULSE are “1”. Thus, the AND circuits 325 and 326 output “0”, and LATCH_IN thereby changes from “1” to “0”. The output from the clock output circuit 330 thus ends.

Though the operation of the pulse generator circuit when it generates two pulses is described above, the operation is the same when it generates one pulse or three pulses, and it can output a clock of a desired number of pulses. For example, if the scan clock SCK indicated by (b) of FIG. 4 is one pulse, one pulse of delay test clock SCK0 is output. If the scan clock SCK indicated by (b) of FIG. 4 is three pulses, three pulses of delay test clock SCK0 are output.

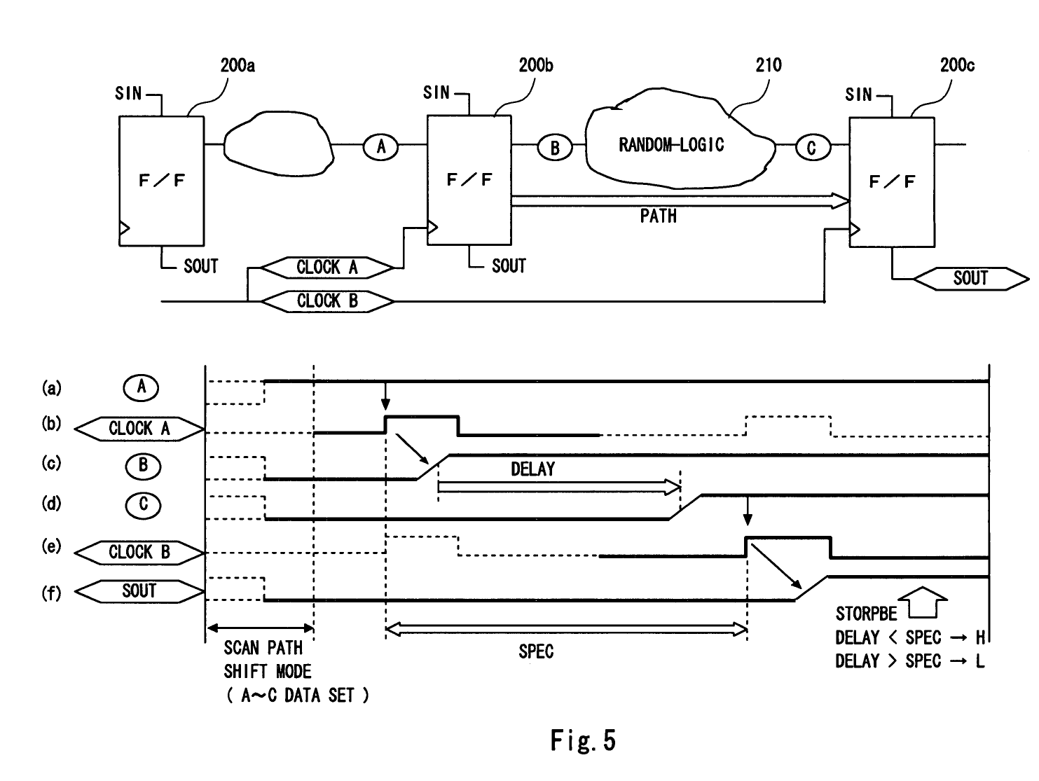

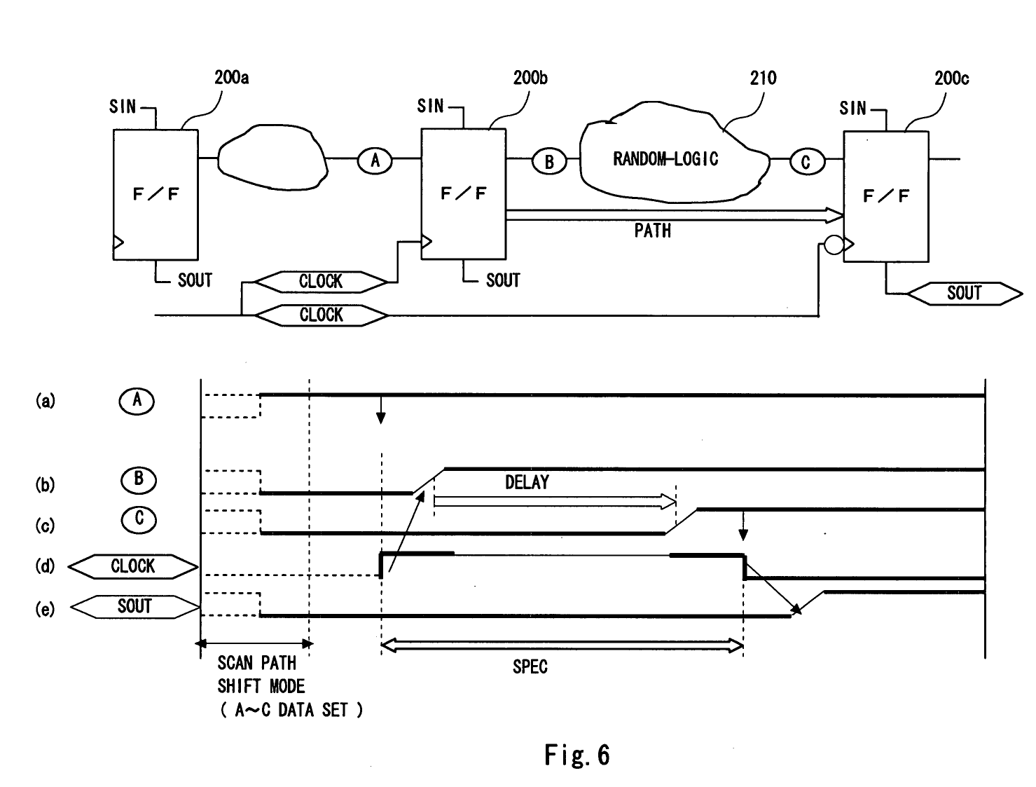

The process of the delay test according to this embodiment is described hereinafter with reference to FIGS. 5 and 6. The scan F/Fs 200 operates during the delay test alternately in the scan mode and in the normal operation mode. FIG. 5 shows the case where the pulse generator circuit 5 generates two pulses of delay test clock SCK0. FIG. 6 shows the case where the pulse generator circuit 5 generates one pulse of delay test clock SCK0.

As shown in FIG. 5, if the scan F/Fs in the input stage and the output stage of the tested circuit 210 are both POS-F/F, the delay test is performed using a two-pulse clock. The process of the delay test first switches the scan F/Fs 200 that form a scan chain to the scan mode with a scan enable signal SE, and transfers an initial value by inputting a scan clock SCK. In this example, the initial value transferred to the scan F/F 200b is retained and also output from the F/F when the scan clock SCK is “0”.

Then, after switching the scan F/Fs 200 to the normal operation mode by the scan enable signal SE, the pulse generator circuit 5 generates two-pulse clock by Control signal, scan clock SCK, and START_PULSE.

In FIG. 5, the first clock of the two pulses is represented by “clock A” and the second clock is represented by “clock B” as shown in (b) and (e) of FIG. 5. The scan F/F 200b latches a signal at the point A before the first clock rises as indicted by (a) of FIG. 5, and supplies the latched signal at the point A to the point B at the timing when the first clock rises as indicted by (c) of FIG. 5. In the delay test, the signal value at the point B output from the F/F 200b by the initial value is different from the signal value transferred from the point A to B to be tested. The tested circuit 210 operates by receiving the signal at the point B and outputs an operating result to the point C after delay time Delay has passed as indicated by (d) of FIG. 5. The scan F/F 200c latches and outputs the signal at the point C at the timing when the second clock rises as indicated by (f) of FIG. 5.

Then, the process switches the scan F/Fs 200 to the scan mode by the scan enable signal SE and transfers the latched signal to the scan-out terminal SOUT by supplying the scan clock SCK. It then compares the operating result acquired from the scan-out terminal SOUT with a predetermined expected value to check if failure occurs due to delay of the tested circuit 210.

If the delay time Delay of the tested circuit 210 falls within Spec period in FIG. 5, the operating result from the F/F 200c matches the expected value. If it does not falls within Spec period, the operating result does not match the expected value, meaning that failure occurs.

On the other hand, if the scan F/F in the input stage of the tested circuit 210 is POS-F/F and the scan F/F in the output stage is NEG-F/F as shown in FIG. 6, the delay test is performed using one-pulse clock. The delay test process first sets the initial value just like in FIG. 5 and generates one-pulse clock in the pulse generator circuit 5 by Control signal, scan clock SCK, and START_PULSE.

In FIG. 6, the one pulse clock is represented by “clock” as shown in (d) of FIG. 6. The scan F/F 200b latches a signal at the point A before the clock rises as indicted by (a) of FIG. 6, and supplies the latched signal at the point A to the point B at the timing when the clock rises as indicted by (b) of FIG. 6. The tested circuit 210 operates by receiving the signal at the point B and outputs an operating result to the point C after delay time Delay has passed as indicated by (c) of FIG. 6. The scan F/F 200c latches and outputs the signal at the point C at the timing when the clock falls as indicated by (e) of FIG. 6. After that, the process the process transfers the latched signal to SOUT terminal and compares it with an expected value just like in FIG. 5.

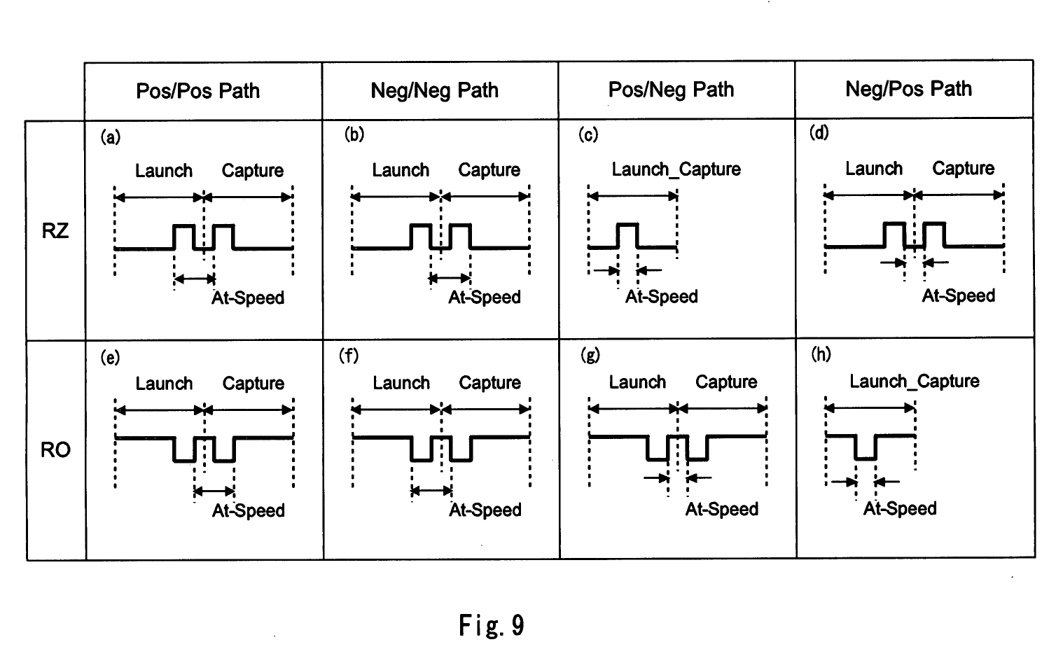

As described in the foregoing, this embodiment indicates the number of pulses of the delay test clock from the outside of the LSI and extracts the clock signal pulses from the multiplied oscillator clock pulses generated by the PLL or the like by using the pulse generator for use in the test. It is thereby possible to generate a clock having a given number of pulses inside the LSI. This enables the delay test using a multiplied clock generated by the PLL regardless of the path in the circuit having both POS-F/F and NEG-F/F. It is thus possible to perform the tests of all the patterns in FIG. 9 with a desired frequency clock. Since this invention eliminates the need for a high-performance tester, it allows for low-cost testing. Reduction in test costs lead to reduction in device manufacturing costs.

The circuit configuration of FIG. 1 uses the same line for a pulse number setting clock line for setting the number of pulses to the pulse generator circuit and a scan clock (normal operation clock) used for the scan test. Further, it includes a selector circuit in the output side of the pulse generator circuit.

This configuration has the following advantages. First, it reduces the number of terminals to be used for testing. It also reduces the number of test terminals by using the same line for the scan clock and the pulse number setting clock line to the pulse generator circuit. The number of terminals that can be used for testing is limited in practice and therefore reduction of the number of terminals for testing has been an issue.

Further, since a pulse number setting waveform to the pulse generator circuit and a waveform output from the pulse generator circuit are the same, it is possible to perform the delay test directly from a tester simply by changing the test pattern so as to switch the selector circuit (multiplexer) in the output side of the pulse generator circuit. This facilitates analysis upon occurrence of failure on the tester. If a problem occurs in a product test performed for removing inferior products by using a tester, analysis is needed and the frequency of the delay test clock SCK0 is changed at this time. Since the output clock frequency of the PLL can be only changed within a limited frequency range, it is difficult to change the frequency inside the LSI. Since the tester can flexibly set the clock waveform and the frequency, the present invention has the advantage of easy analysis with the same pattern.

Though the above embodiment describes the case where Control signal which controls the counter operation of the pulse generator circuit and scan enable signal SE are different from each other, they may be the signals input from the same scan mode control terminal SMC. In this case, it is possible to set the number of pulses applied after the scan shifting to the pulse number control circuit.

Though the above embodiment describes the case where the pulse generator circuit generates one, two, or three pulses, the present invention is not limited thereto, and it is possible to select and generate a given number of pulses. It is thereby applicable to various test patterns generated by ATPG tool.

It is apparent that the present invention is not limited to the above embodiment that may be modified and changed without departing from the scope and spirit of the invention.

What is claimed is:

1. An integrated circuit device performing a delay test using scan path technique, comprising:
a pulse generator circuit generating delay test clock pulses of which number is according to an input pulse number control signal; and
a scan path test circuit tested with the delay test clock pulses.

2. The integrated circuit device of claim 1, wherein the number of the delay test clock pulses generated by the pulse generator circuit is equal to the number of pulses of the input pulse number control signal.

3. The integrated circuit device of claim 1, further comprising:
a clock pulse input terminal for inputting scan shift clock pulses to the scan path test circuit, wherein the pulse number control signal is input through the clock pulse input terminal.

4. The integrated circuit device of claim 1, wherein the pulse generator circuit comprises a counter circuit counting the number of pulses of the pulse number control signal, the counted number used as the number of the delay test clock pulses.

5. The integrated circuit device of claim 4, further comprising:
a scan mode control terminal for inputting a scan enable signal for switching operation modes of the delay test, wherein a control signal for controlling counter operation of the counter circuit is input through the scan mode control terminal.

6. The integrated circuit device of claim 1, wherein the pulse generator circuit comprises a pulse selector circuit selecting pulses of which number is according to the pulse number control signal from input clock pulses to generate the delay test clock pulses.

7. The integrated circuit device of claim 6, wherein the selector circuit comprises an output period determination circuit determining a period to output the delay test clock pulses according to the number of pulses of the pulse number control signal, and a clock output circuit outputting the input clock pulses as the delay test clock pulses during the determined period.

8. The integrated circuit device of claim 6, further comprising:
a PLL circuit multiplying a frequency of an input signal, wherein the input clock pulses are output from the PLL circuit.

9. The integrated circuit device of claim 4, wherein the pulse generator circuit comprises a pulse selector circuit selecting pulses of which number is according to the pulse number control signal from input clock pulses to generate the delay test clock pulses.

10. The integrated circuit device of claim 9, wherein the selector circuit comprises an output period determination circuit determining a period to output the delay test clock pulses according to the number of pulses of the pulse number control signal, and a clock output circuit outputting the input clock pulses as the delay test clock pulses during the determined period.

11. The integrated circuit device of claim 9, further comprising:
a PLL circuit multiplying a frequency of an input signal, wherein the input clock pulses are output from the PLL circuit.

12. A testing device for an integrated circuit device, comprising:
a test board on which an integrated circuit device is to be mounted for testing, the integrated circuit device comprising a pulse generator circuit generating delay test clock pulses of which number is according to an input pulse number control signal, and a scan path test circuit tested with the delay test clock pulses; and
a clock oscillator mounted on the test board and generating clock pulses to be input to a pulse generator circuit.

13. The testing device of an integrated circuit device of claim 12, wherein the pulse generator circuit comprises a pulse selector circuit selecting pulses of which number is according to the pulse number control signal from input clock pulses to generate the delay test clock pulse.

14. The testing device of an integrated circuit device of claim 13, wherein the integrated circuit device comprises a PLL circuit multiplying a frequency of an input signal, and the input clock pulses are output from the PLL circuit.

15. The testing device of an integrated circuit device of claim 14, wherein the clock oscillator mounted on the test board generates the clock pulses to be input to the PLL circuit.

16. An integrated circuit device comprising;
circuitry to be tested; and
flip-flops interconnected into a scan path on which the circuitry to be tested is located, the scan path operating alternately in scan shift mode and normal operation mode, and the scan path operating in the normal operation mode with pulses of which number is according to an input pulse number control signal.

17. The integrated circuit device of claim 16, further comprising a pulse generator circuit generating the pulses of which number is according to the input pulse number control signal.

18. The integrated circuit device of claim 17, wherein the number of pulses generated by the pulse generator circuit is equal to the number of pulses of the input pulse number control signal.
